(19) United States
(12) Patent Application Publication
(10) Pub. No.: US 2026/0280243 A1
(43) Pub. Date: Sep. 17, 2026

(54) POWER CABLE INSERTION AND REMOVAL DEVICE

(71) Applicant: Lenovo Global Technology (United States) Inc., Morrisville, NC (US)

(72) Inventors: Robert R. Wolford, Strongsville, OH (US); Ananthakrishnan Narayanan, Durham, NC (US); Brian C. Totten, Durham, NC (US); James C. Loebach, Cary, NC (US); Timothy Glen Hanna, Apex, NC (US)

(21) Appl. No.: 19/080,875

(22) Filed: Mar. 16, 2025

(51) Int. Cl. H02G 1/00; H05K 7/14

(52) U.S. Cl. CPC H02G 1/00; H05K 7/1492

(57) ABSTRACT

An apparatus includes a rigid elongate shaft having a clip fastener at a distal end and a handle at a proximal end. The clip fastener has a laterally directed clip opening dimensioned to receive a strain relief member of a rigid electrical plug body of a flexible power cable. The clip fastener secures the strain relief member and is positioned between a rigid electrical plug body and a ridge of the strain relief member. With the clip fastener secured to the strain relief member, pushing the handle in a distal direction toward a receptacle of a power distribution unit (PDU) causes a set of electrically conductive elements secured to the rigid electrical plug body to connect electrically with the receptacle and pulling the handle in a proximal direction away from the receptacle of the PDU causes the set of electrically conductive elements to be disconnected from the receptacle.

### BACKGROUND

The present disclosure relates to systems and methods for forming electrical connections between a power cable and an electrical receptacle.

### Background of the Related Art

In large datacenters, server computers are typically installed into standard enterprise server racks. In the server rack, power distribution units (PDUs) are used to distribute large power feeds coming into the server rack into an array of individual receptacles. Each power supply unit (PSU) on every server has a power cable that must be plugged into one of the receptacles on one of the PDUs. If a server rack is filled with server computers, networking device and other equipment, there may be no rack units (“U”s) left in the rack for positioning of the PDUs. In that case, one or more strip PDUs may be installed in the left and right 0U side pockets of the server rack by attaching the strip PDUs to the back side of a rear flange.

A problem with installing strip PDUs in the side pockets of the server rack arises when deep servers are installed in the rack. The Electronic Industry Association (EIA) front and rear flanges in the server rack are at industry standard locations. If the servers installed in the server rack are deeper than the distance between the standard front and rear EIA flanges, the rear of the servers will extend past the rear EIA flange. However, since the strip PDUs are attached to the rear EIA flange, the receptacles of the PDUs are recessed several inches from the rear face of the deep servers. Furthermore, the width of a gap between the deep server and an adjacent wall of the server rack is only about 1U wide (1.75 inch). The narrow gap and deep recess prevent a person from gripping the plug at the end of the power cord and plugging it into a PDU receptacle, but relocating the PDUs or modifying the rack leads to other problems.

### BRIEF SUMMARY

Some embodiments provide an apparatus. The apparatus comprises a rigid elongate shaft defining a longitudinal path between a proximal end and a distal end. A clip fastener is at the distal end of the rigid elongate shaft, wherein the clip fastener has a laterally directed clip opening dimensioned to receive a strain relief member of a rigid electrical plug body at a distal end of a flexible power cable, and wherein the clip fastener is configured to receive and secure the strain relief member with the clip fastener positioned between the rigid electrical plug body and a ridge of the strain relief member. The apparatus further comprises a handle at the proximal end of the rigid elongate shaft, wherein, with the clip fastener secured to the strain relief member, an application of pushing force to the handle in a distal direction toward a receptacle of a power distribution unit in line with the longitudinal path causes a set of electrically conductive elements secured to the rigid electrical plug body to connect electrically with the receptacle and an application of pulling force to the handle in a proximal direction away from the receptacle of the power distribution unit causes the set of electrically conductive elements to be disconnected from the receptacle.

Some embodiments provide a method of using the apparatus described herein. The method may comprise positioning the rigid elongate shaft along the power cable with the laterally directed clip opening facing the strain relief member of the rigid electrical plug body, pushing the strain relief member into the clip opening until the clip fastener is secured to the strain relief member with the clip fastener positioned between the rigid electrical plug body and a ridge of the strain relief member, pushing the handle in the distal direction toward the receptacle until the set of electrically conductive elements form an electrical connection with the receptacle, and pulling the handle in a proximal direction away from the receptacle until the set of electrically conductive elements are disconnected from the receptacle. It should be understood that the disconnection from the receptacle may only be required when the device (server) coupled to the power cable is being removed from the server rack.

### BRIEF DESCRIPTION OF THE SEVERAL VIEWS OF THE DRAWINGS

FIG. 1 is a schematic plan view of a standard enterprise server rack containing a deep server and a pair of power distribution units (PDUs) installed in the side pockets of the server rack.

FIG. 2A is a perspective view of an insertion and removal device in a position to be fastened to a power cable

FIG. 2B is a diagram of the insertion and removal device secured to the power cable according to one embodiment. and used to manipulate the power cable to connect electrically with one of the power distribution units despite the power distribution unit being inaccessible to a person's hand.

FIG. 3 is a diagram of the insertion and removal device secured to the power cable and being manipulated to align the electrically conductive elements of the rigid plug at the distal end of the power cable with a receptacle of the power distribution unit prior to forming an electrical connection according to one embodiment.

FIG. 4A is a bottom side view of the insertion and removal device secured to the power cable.

FIG. 4B is a diagram of the server rack with the deep server and two power distribution units as shown in FIG. 1 after a first insertion and removal device has been used to connect electrically of a first power cable to a first power distribution unit and a second insertion and removal device is aligned with a second power distribution unit prior to forming an electrical connection.

FIG. 5A is a cross-sectional view of the insertion and removal device taken along line 5A-5A in FIG. 4A according to one embodiment.

FIG. 5B is a cross-sectional view of the insertion and removal device taken along line 5B-5B in FIG. 4A according to one embodiment.

FIG. 5C is a cross-sectional view of the insertion and removal device taken along line 5C-5C in FIG. 4A according to one embodiment.

FIG. 6A is a cross-sectional view of the insertion and removal device as in FIG. 5A but without the power cable according to one embodiment.

FIG. 6B is a cross-sectional view of the insertion and removal device as in FIG. 5B but without the power cable according to one embodiment.

FIG. 6C is a cross-sectional view of the insertion and removal device as in FIG. 5C but without the power cable according to one embodiment.

FIGS. 7A and 7B are diagrams of alternative configurations of a handle at the proximate end of the elongate rigid shaft according to additional embodiments.

FIG. 8 is a diagram of an alternative configuration of the elongate rigid shaft including a bend according to one embodiment.

FIG. 9A is a perspective view of an IEC 14 male power cable connector or plug.

FIG. 9B is a perspective view of an IEC 13 female power cable connector or plug.

### DETAILED DESCRIPTION

Some embodiments provide an apparatus. The apparatus comprises a rigid elongate shaft defining a longitudinal path between a proximal end and a distal end. A clip fastener is provided at the distal end of the rigid elongate shaft, wherein the clip fastener has a laterally directed clip opening dimensioned to receive a strain relief member of a rigid electrical plug body at a distal end of a flexible power cable, and wherein the clip fastener is configured to receive and secure the strain relief member with the clip fastener positioned between the rigid electrical plug body and a ridge of the strain relief member. The apparatus further comprises a handle at the proximal end of the rigid elongate shaft, wherein, with the clip fastener secured to the strain relief member, an application of pushing force to the handle in a distal direction toward a receptacle of a power distribution unit in line with the longitudinal path causes a set of electrically conductive elements secured to the rigid electrical plug body to connect electrically with the receptacle and an application of pulling force to the handle in a proximal direction away from the receptacle of the power distribution unit causes the set of electrically conductive elements to be disconnected from the receptacle.

The apparatus may be referred to as a “cable extender” or an “insertion and removal device” for a power cable or cord. The apparatus is designed with a distal end having a clip fastener that is easily securable to the strain relief member of a rigid electrical plug body and a proximal end forming a handle. Accordingly, a person may grasp or grip the handle with the fingers of one hand and extend the apparatus so that the rigid electrical plug body is connectable with a receptacle that is not accessible to the person's hand. The apparatus has cross-sectional dimensions that is much less than that of an average person's hand such that the rigid electrical plug body may be connected to the receptacle through a narrow space or opening between structural elements of a configured server rack. Furthermore, a person may subsequently grasp or grip the handle with the fingers of one hand and withdraw the apparatus so that the rigid electrical plug body is disconnectable from the receptacle.

An electrical plug at the end of a power cable is designed with a durable, insulated housing to protect users from electrical shock. The electrical plug body is typically made of a rigid plastic or rubber. The electrical plug supports electrically conductive prongs or pins, usually made of brass or another electrically conductive metal. The electrically conductive prongs or pins, such as flat blades and round pins, extend from an engagement face of the rigid electrical plug body and serve as the electrical contacts that fit into corresponding slots in an electrical receptacle or socket. The geometry of the prongs or pins varies by country and electrical standard but generally includes two or three prongs arranged in a specific configuration to ensure proper polarity and grounding. The prongs or pins are often flat or round to correspond to the geometry of the slots or holes in the receptable to establish independent electrical communication with contacts inside the receptacle for each of the prongs or pins. Within the electrical plug, the prongs are connected to insulated conductors that extend within the power cable to ensure a secure and efficient transfer of electricity while preventing short circuits or electrical faults. Without limitation, the power cords and the power distribution units may be made in accordance with any of the standards of the National Electrical Manufactures Association (NEMA). The power cable is preferably designed to carry alternating current (AC).

The strain relief member is located where the flexible cable enters the rigid plug body or housing and is constructed from durable materials, such as rubber, plastic, or molded thermoplastic elastomers. The purpose of the strain relief member is to protect the internal wiring of the flexible cable from damage caused by pulling, bending, or twisting forces. The strain relief member may take the form of a molded sleeve that surrounds the flexible cable, distributing forces over a larger area rather than concentrating them at the connection point with the rigid plug body. Accordingly, the strain relief member helps to prevent fraying, conductor breakage, or electrical faults, ultimately extending the lifespan of the power cord and ensuring safe and reliable operation.

In one option, the strain relief member may be an integral part of the rigid plug body, extending in the direction of the flexible cable. Furthermore, the strain relief member may have a cross-sectional profile that is cylindrical, oval or irregular and may have a circumferential ridge or collar at the proximal end of the strain relief member. The clip fastener is configured to receive and secure the strain relief member with the clip fastener positioned between the rigid electrical plug body and a ridge of the strain relief member. Therefore, the clip fastener is connectable to a narrow dimension or diameter segment in a mid-point of the strain relief member with the ridge on the proximal side of the clip fastener and a larger portion of the rigid electrical plug body on the distal side of the clip fastener. Pushing the handle in a distal direction toward a receptacle of a power distribution unit causes a distal face of the clip fastener to push against the rigid electrical plug body such that the electrical connection between the set of electrically conductive elements and the receptacle may be formed. Subsequently, an application of pulling force to the handle in a proximal direction away from the receptacle causes a proximal face of the clip fastener to push against the circumferential ridge or collar around the proximal end of the strain relief member such that the set of electrically conductive elements are disconnected from the receptacle. In one example, the clip fastener secured to the strain relief member, the distal face or edge of the clip fastener may abut the rigid electrical plug body and the proximal face or edge may abut the ridge or collar of the strain relief member.

In some embodiments, the clip fastener is secured to the power cable before forming the electrical connection with the receptacle and remains secured to the power cable over a duration of the electrical connection so that the handle is ready to be used to disconnect the electrical connection. Accordingly, connecting one end of some number (“X”) of power cables from a power consuming device, such as a server, to a power distribution unit that is located in a recessed area that is inaccessible to a human hand will remain an equal number (“X”) of the apparatus (i.e., a cable extender or an insertion and removal device).

In some embodiments, the handle may take any form that facilitates manually guiding or directing the set of electrically conductive elements into alignment with the slots of an intended receptacle, application of pushing force to the rigid elongate shaft to cause formation of the electrical connection, and application of pulling force to the rigid elongate shaft to disconnect the set of electrically conductive elements from the receptacle. Non-limiting examples of the handle include a finger loop, a crossbar (i.e., a T-shaped handle) or a paddle. In reference to a finger loop, an index finger may be positioned inside the finger loop and a thumb of the same hand as the index finger may then press on the distal end of the finger loop. With a distal portion of the finger loop gripped between the index finger and thumb, the orientation and translation of the apparatus may be easily controlled to accomplish the formation or disconnection of an electrical connection. Of course, the elongate shaft needs to be long enough so that the electrical plug may form an electrical connection with the intended receptacle while the handle is still accessible to the human hand. In one non-limiting example, the elongate rigid shaft and the handle may have a combined length that is sufficient to extend, with the clip fastener secured to the strain relief member and with the set of electrically conductive elements forming an electrical connection with the receptacle, from the strain relief member to a point rearward of a rear edge of a deep server that extends rearward of a rear flange of a server rack. One example of a deep server chassis is the Lenovo DW612S, which extends about 10 inches further rearward of the rear flange of a standard EIA server rack.

In some embodiments, the rigid elongate shaft is made with a polymeric material, metal or composite material containing carbon fiber. While the elongate shaft may be made from a wide variety of materials, the elongate shaft should be rigid so as not to deflect appreciably as it is being directed toward the receptable and pushed to form the electrical connection. A couple of preferred polymeric materials include polyethylene terephthalate glycol-modified (PETG) or polylactic acid (PLA), which have both been found to be effective. Optionally, the apparatus may be formed as a single integral piece, such that the apparatus may be produced in large efficient batches via an injection molding process. However, the apparatus may also be produced by three-dimensional printing or other manufacturing process.

In some embodiments, with the clip fastener secured to the strain relief member, the elongate rigid shaft and the clip fastener have a very low profile to avoid contributing to the problem of extending through the narrow space available to access the receptacle. In one option, the clip fastener and elongate shaft may have a cross-sectional profile that is inscribed within a cross-sectional profile of the rigid electrical plug body. In other words, neither the clip fastener nor the elongate shaft extend laterally beyond the cross-sectional profile of the rigid electrical plug body such that any power cable can be connected to a receptacle through any space that the rigid electrical plug body itself can pass through.

In some embodiments, the longitudinal path of the rigid elongate shaft may include a bend so that the handle portion is disposed at an angle from a distal portion of the rigid elongate shaft that forms the clip fastener. This may be advantageous in situations where the narrow space for accessing the receptable is not linear or if the receptable is so close to a wall that handle would be too close to the wall.

In some embodiments, the set of electrically conductive elements are prongs extending from the rigid electrical plug body, and wherein the receptacle includes a set of slots for receiving the prongs. When the clip fastener is secured to the strain relief member, the rigid electrical plug body is held in a position so that the set of electrically conductive elements extend in the distal direction defined by a distal end portion of the elongate rigid shaft. Accordingly, directing the elongate rigid shaft toward the receptacle not only positioned the rigid electrical plug body in front of the receptacle, but also causes an axial direction of the set of electrically conductive elements to be parallel with an axial direction of the slots in the receptacle. The user may still need to rotate the apparatus about the axis of the elongate rigid shaft to orient the set of electrically conductive elements to match up with the corresponding slots of the receptacle. Of course, if the desired rotational orientation of the electrical plug is determined when the apparatus is being secured to the power cable, then the necessary rotational orientation can be easily predetermined by the user and only very minor rotational adjustments may be needed.

In some embodiments, the apparatus may further comprise one or more laterally directed cable dressing clips secured to the elongate shaft between the clip fastener and the handle. For example, each of the cable dressing clips may be a press-fit clip that is secured to the power cable by manually pressing the power cable into an opening in the cable dressing clip. Optionally, the cable dressing clips may be substantially similar design to the clip fastener, except that the cable dressing clips are sized to secure the flexible cable whereas the clip fastener is sized to secure the strain relief member. Accordingly, the cable dressing clips will typically be smaller than the clip fastener. The one or more cable dressing snaps may be positioned periodically along the length of the elongate rigid shaft to maintain neatness and organization of the flexible cable portion of the power cable when many units of the apparatus are used side by side. For example, the cable dressing snaps may prevent a power cable connected to an upper receptacle of a power distribution unit from drooping downward and blocking a lower receptacle of the power distribution unit. Similarly, using the apparatus with cable dressing snaps with several power cables may prevent those power cables from drooping downward and preventing or resisting the disconnection of a power cable from a lower receptacle of the power distribution unit. In one option, the one or more laterally directed cable dressing clips may include from two to four cable dressing clips, which may be more or less evenly spaced along the length of the elongate rigid shaft. While plastic tie wraps or other fasteners could be used to secure the flexible cable to the elongate rigid shaft along its length, the cable dressing clips are preferred because they require less time and effort to connect and disconnect while maintaining a low profile.

In some embodiments, the clip fastener is a press-fit clip that is secured to the strain relief member of the power cable by manually pressing the strain relief member into the clip opening. In one option, the clip fastener may have an interior profile that includes a major arc of a circle. By having an interior diameter that is the same or similar to the outer diameter of strain relief member, once the strain relief member is forcibly pressed through the clip opening into the center of the clip fastener, the major arc prevents the strain relief member from coming unfastened absent an equal or greater force directing the strain relief member out of the clip opening. For example, the clip opening may be smaller than an outer diameter of the strain relief member of the power cable, and the clip fastener may have first and second jaws that flex outward when the strain relief member is pressed therebetween. The clip fastener opening is preferably directed away from the rigid elongate shaft and the first and second jaws are symmetrical.

In some embodiments, the power distribution unit is positioned in a side pocket of the server rack and secured to the rear flange in the server rack with the receptacles facing the rear of the server rack. The side pocket is not accessible to an adult human hand because the side pocket is less than 2 inches wide (i.e., about 1.75 inches wide; referred to as “0U”). This configuration is typically is not tolerated, such that the power distribution unit must be moved to a rear door of the server rack whenever a deep server is installed in the standard server rack or a server might have to be removed from the server rack to make a 1U bay available for a power distribution unit.

Some embodiments provide a method of using the apparatus described herein. The method may comprise positioning the rigid elongate shaft along the power cable with the laterally directed clip opening facing the strain relief member of the rigid electrical plug body, pushing the strain relief member into the clip opening until the clip fastener is secured to the strain relief member with the clip fastener positioned between the rigid electrical plug body and a ridge of the strain relief member, pushing the handle in the distal direction toward the receptacle until the set of electrically conductive elements form an electrical connection with the receptacle, and pulling the handle in a proximal direction away from the receptacle until the set of electrically conductive elements are disconnected from the receptacle. It should be understood that the disconnection from the receptacle may only be required when the device (server) coupled to the power cable is being removed from the server rack.

Embodiments provide the technical advantage of allowing a person to plug a power cable into a receptacle of a power distribution unit that is installed in an area that a person's hand cannot access due to the small or narrow dimensions of area in front of the power distribution unit. Optionally, the apparatus may be provided only to those personnel who are authorized to connect power to a particular device. In other words, limited access to the apparatus may be used to implement a certain degree of restriction over who is authorized or allowed to plug in the device.

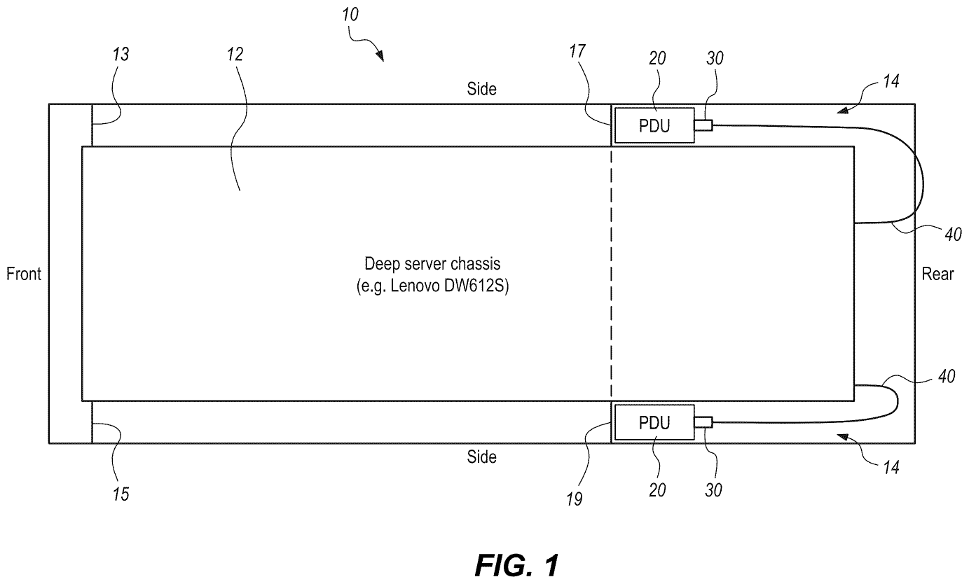

FIG. 1 is a schematic plan view of a standard enterprise server rack 10 containing a deep server 12 and a pair of power distribution units (PDUs) 20 installed in the side pockets 14 of the server rack 10. The standard enterprise server rack 10 includes a pair of front EIA flanges 13, 15 and a pair of rear EIA flanges 17, 19 that are positioned at industry standard locations. However, the deep server 12 is larger than a typical server and is even deeper than the distance between the standard front EIA flanges 13, 15 and rear EIA flanges 17, 19. Specifically, the deep server 12 extends about 10 inches beyond the rear of the rear EIA flanges 17, 19. Furthermore, the width of the side pocket 14 between the deep server and an adjacent side wall of the server rack 10 is only about 1U wide (1.75 inch).

Power distribution units (PDUs) are used to distribute large power feeds coming into the server rack 10 into an array of individual receptacles. Each power supply unit (PSU) on every server 12 has a power cable 40 that must be plugged into one of the receptacles on one of the PDUs. If a server rack is filled with server computers, networking device and other equipment, there may be no rack units (“U”s) left in the rack for positioning of the PDUs. In that case, one or more strip PDUs 20 may be installed in the left and right 0U side pockets 14 of the server rack 10 by attaching the strip PDUs 20 to the back side of the rear flanges 17, 19.

Since the strip PDUs 20 are attached to the rear EIA flanges 17, 19, the receptacles of the PDUs 20 are recessed several inches from the rear face of the deep server 12. The narrow and deep side pockets 14 (about 1.75 inches wide and about 10 inches deep) prevent a person from gripping an electrical plug 30 at the end of the power cord 40 from the server 12 or other servers and plugging it into a receptacle of the PDU 20 but relocating the PDUs 20 or modifying the server rack 10 leads to other problems. Accordingly, the illustration electrical connections between the electrical plugs 30 and the PDUs 20 are difficult to accomplish.

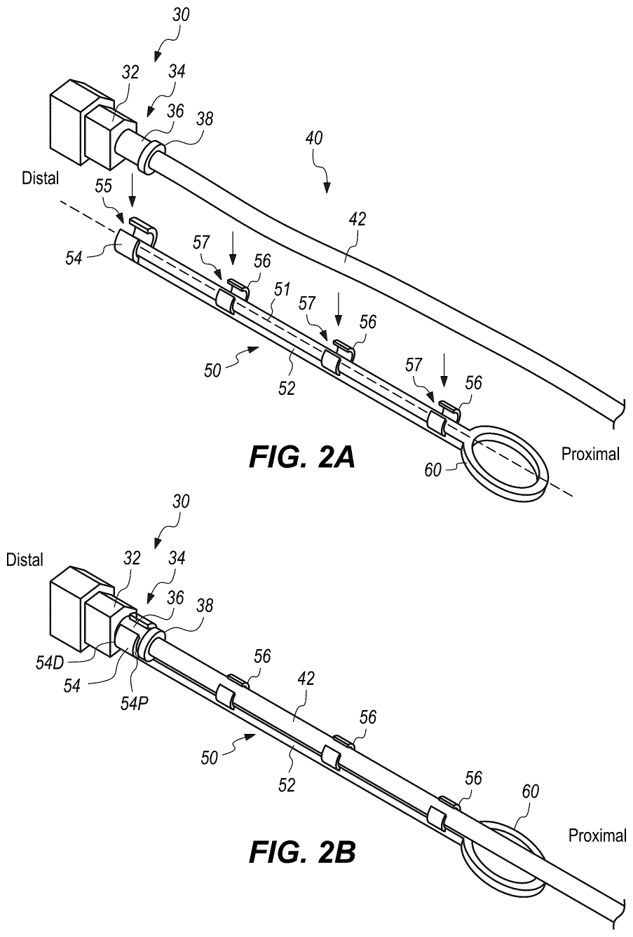

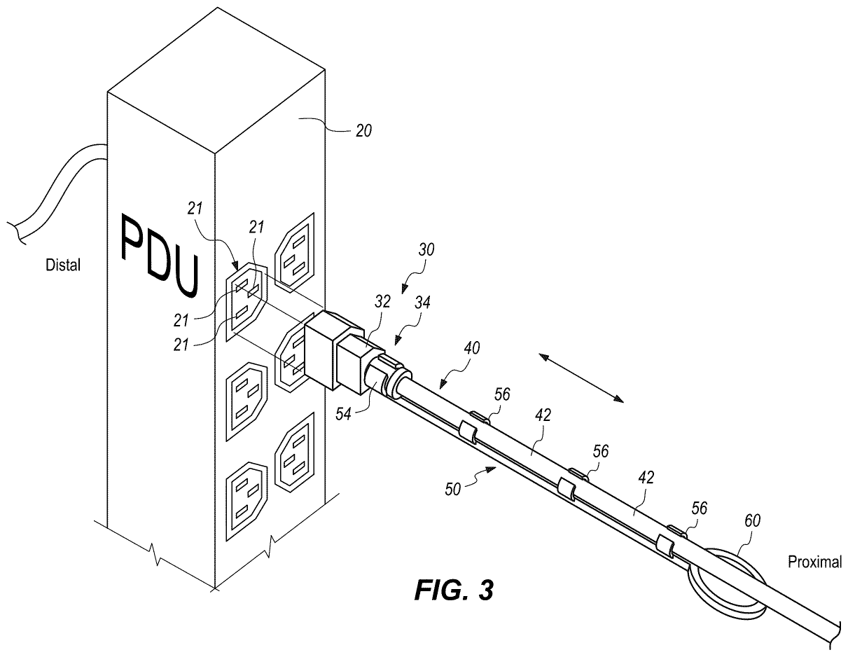

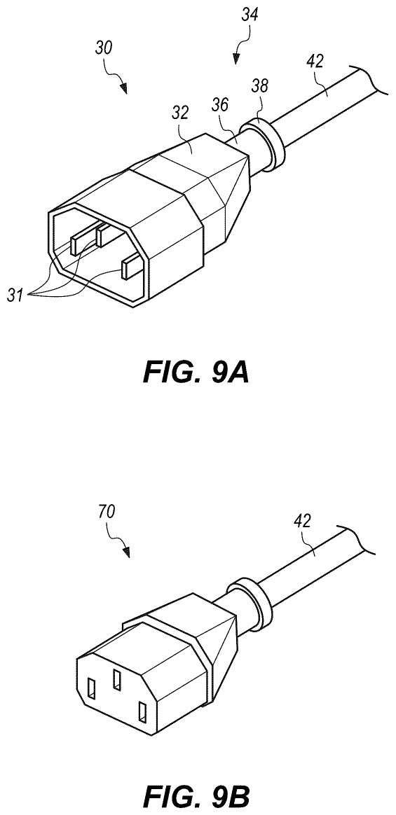

FIG. 2A is a perspective view of an insertion and removal device (the “apparatus”) 50 in a position to be fastened to a power cable 40. The power cable 40 includes an electrical plug 30 at a distal end of the power cable 40. The electrical plug 30 is designed with a durable, insulated housing to protect users from electrical shock. The electrical plug body 32 is typically made of a rigid plastic or rubber and supports electrically conductive prongs or pins (not show; but see FIG. 9A), usually made of brass or another electrically conductive metal. Within the electrical plug 30, the prongs are connected to insulated conductors that extend within the power cable to ensure a secure and efficient transfer of electricity while preventing short circuits or electrical faults. Without limitation, the power cable 40 and the power distribution unit 20 (see FIGS. 1 and 3) may be made in accordance with any of the standards of the National Electrical Manufactures Association (NEMA). The power cable is preferably designed to carry alternating current (AC).

The strain relief member 34 is located where the flexible cable 42 enters the rigid plug body or housing 32 and is constructed from durable materials, such as rubber, plastic, or molded thermoplastic elastomers. The purpose of the strain relief member 34 is to protect the internal wiring of the flexible cable 42 from damage caused by pulling, bending, or twisting forces. The strain relief member 34 may take the form of a molded sleeve that surrounds the distal end of the flexible cable 42, distributing forces over a larger area rather than concentrating them at the connection point with the rigid plug body 32. Accordingly, the strain relief member 34 helps to prevent fraying, conductor breakage, or electrical faults, ultimately extending the lifespan of the power cord and ensuring safe and reliable operation. As shown, the strain relief member 34 is integrally formed with the rigid plug body 32, extending in the direction of the flexible cable 42. Furthermore, the strain relief member may have a mid-section 36 having a cross-sectional profile that is cylindrical, oval or irregular and may have a circumferential ridge or collar 38 at the proximal end of the strain relief member 34.

The insertion and removal device (the “apparatus”) 50 includes a rigid elongate shaft 52 defining a longitudinal path 51 (illustrated as a dashed line) between a proximal end (to the right side of FIG. 2A) and a distal end (to the left side of FIG. 2A). A clip fastener 54 is provided at the distal end of the rigid elongate shaft 52, wherein the clip fastener 54 has a laterally directed clip opening 55 dimensioned to receive the mid-section 36 of the strain relief member 34 between the rigid electrical plug body 32 and the ridge 38 of the strain relief member 34. The apparatus 50 further includes a handle 60 at the proximal end of the rigid elongate shaft 52 and a plurality of cable dressing clips 56 at spaced-apart points along the length of the rigid elongate shaft 52. Each of the cable dressing clips 56 has a clip opening 57 dimensioned to receive the flexible cable 42. The illustrated arrows 44 indicate the direction for pressing the power cable 40 into the openings 55, 57 of the clip fastener 54 and the cable dressing clips 56 to secure the power cable 40 to the insertion and removal device 50.

FIG. 2B is a diagram of the insertion and removal device 50 secured to the power cable 40. The clip fastener 54 secures the strain relief member 34 with the clip fastener 54 positioned about mid-section 36 between the rigid electrical plug body 32 and the ridge 38 of the strain relief member 34. It should be recognized that application of pushing force to the handle 60 in a distal direction toward a receptacle of a power distribution unit (not shown; see FIG. 3) causes a distal face 54D of the clip fastener 54 to push against the rigid electrical plug body 32 such that an electrical connection may be formed. Subsequently, an application of pulling force to the handle 60 in a proximal direction away from the receptacle causes a proximal face 54P of the clip fastener 54 to push against the circumferential ridge or collar 38 around the proximal end of the strain relief member 34 such that an electrical connection may be disconnected. The distal face or edge 54D of the clip fastener may abut the rigid electrical plug body 32 and the proximal face or edge 54P may abut the ridge or collar 38. The three cable dressing clips 56 are securing a portion of the flexible cable 42 and prevent the flexible cable from drooping regardless of the orientation of the clip openings 57.

FIG. 3 is a diagram of the insertion and removal device 50 secured to the power cable 40 and being manipulated to align electrically conductive elements (see FIG. 9A) of the electrical plug 30 at the distal end of the power cable 40 with a receptacle 22 of the power distribution unit 20 prior to forming an electrical connection according to one embodiment. The electrically conductive prongs or pins 31 (see FIG. 9A), such as flat blades and round pins, extend from the rigid electrical plug body 32 and serve as the electrical contacts that fit into corresponding slots 21 in an electrical receptacle or socket 22. Without limitation, the electrical plug may be formed consistent with an IEC 14 (International Electrotechnical Commission) power cord connector (male plug).

Gripping the handle 60, a user may manipulate the power cable 40 to connect electrically with the power distribution unit 20 even when the power distribution unit 20 is inaccessible to a person's hand (see FIG. 1). With the clip fastener 54 secured to the strain relief member 34 of the electrical plug 30, application of pushing force to the handle 60 in a distal direction toward the receptacle 22 of the power distribution unit 20 causes the set of electrically conductive elements (not shown; see FIG. 9A) secured to the rigid electrical plug body 32 to connect electrically with the receptacle 22 and an application of pulling force to the handle 60 in a proximal direction away from the receptacle 22 of the power distribution unit 20 causes the set of electrically conductive elements 31 (see FIG. 9A) to be disconnected from the receptacle 22. Although the insertion and removal device 50 is shown underneath the power cable 40, this is not required. Rather, the insertion and removal device 50 may be rotated to any position about the power cable 40 in order to orient the electrically conductive elements 31 with the corresponding slots 21 in the intended receptacle 22.

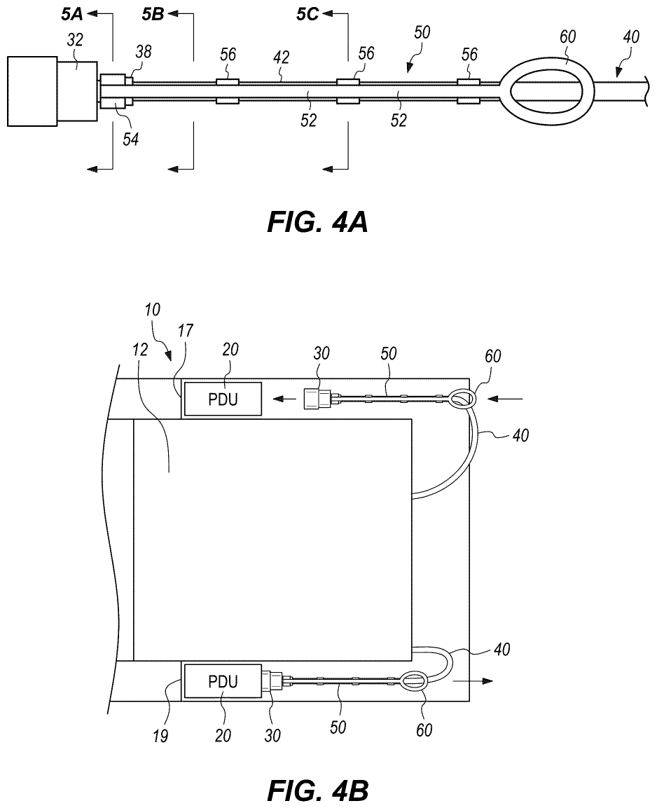

FIG. 4A is a bottom side view of the insertion and removal device 50 secured to the power cable 40. The clip fastener 54 is secured to the strain relief member between the rigid plug body 32 and the ridge or collar 38. Similarly, the flexible cable 42 is secured by the cable dressing clips 56 so that the flexible cable 42 follows the longitudinal path of the elongate rigid shaft 52. Still, the flexible cable 42 extends beyond the proximal end of the insertion and removal device 50 to connect with a device such as the server 12 (see FIG. 1).

FIG. 4B is a diagram of a rear portion of the server rack 10 with the deep server 12 and two power distribution units 20 as shown in FIG. 1. With two insertion and removal devices 50 each secured to a power cable 40 as shown in FIG. 4A, a first electrical connection has been formed between a first power cable 40 and a first power distribution unit 20 (lower portion of FIG. 4B) and a second insertion and removal device 50 is aligning the electrical plug 30 of the second power cable 40 with a second power distribution unit 20 prior to forming an electrical connection (upper portion of FIG. 4B). A user may easily grasp the handle 60 to manipulate and push the electrical plug 30 to connect electrically with the receptacle of the power distribution unit 20 (upper portion of FIG. 4B). The long, narrow space leading to the PDU 20 from the rear of the server rack 10 makes the receptacle inaccessible for a human hand to grip the electrical plug 30 and be able to form the electrical connection. A user may also grasp the handle 60 to pull the electrical plug 30 to disconnect if from the receptacle of the power distribution unit 20 (lower portion of FIG. 4B).

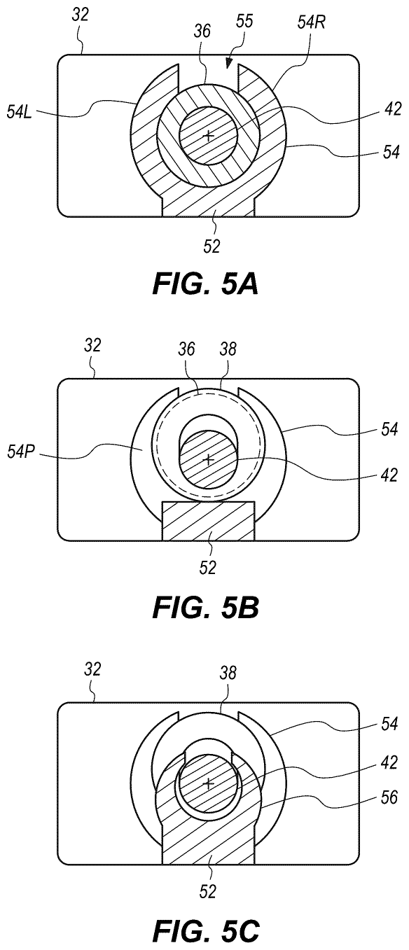

FIG. 5A is a cross-sectional view of the insertion and removal device 50 taken along line 5A-5A in FIG. 4A according to one embodiment. The elongate rigid shaft 54 is disposed along the bottom of the device 50, although orientation of the entire device 50 may be rotated to any position. The clip fastener 54 is formed to the elongate rigid shaft 52 and secures the strain relief member 36 between two jaws 54L, 54R that leave a clip opening 55 that is narrower than the diameter of the strain relief member 36. Accordingly, the strain relief member 36 remains secured by the clip fastener 54 unless an intentional force is applied to push the strain relief member 36 through the clip opening 36. The intentional force must be sufficient to force the two jaws 54L, 54R apart until the opening is wide enough to allow removal of the strain relief member 36. The flexible cable 42 is protected by being surrounded by the strain relief member 36.

As illustrated, the entire cross-sectional profile of the insertion and removal device 50 is inscribed by the cross-sectional profile of the rigid plug body 32. While being inscribed is optional, such a profile assures that the insertion and removal device 50 may be used in any narrow passage that is at least wide enough for the rigid plug body 32.

FIG. 5B is a cross-sectional view of the insertion and removal device 50 taken along line 5B-5B in FIG. 4A according to one embodiment. In this view, only the elongate rigid shaft 54 and the flexible cable 42 are shown in a cross-section. The ridge or collar 38 of the strain relief member 34 is shown as it is positioned on the proximal face 54P of the clip fastener 54. The proximal face 54P also extends behind the ridge or collar 38 to the smaller diameter mid-section 36 (shown by a dashed line) of the strain relief member 34.

FIG. 5C is a cross-sectional view of the insertion and removal device 50 taken along line 5C-5C in FIG. 4A according to one embodiment. The cross-section cuts through the elongate rigid shaft 52 and the cable dressing clip 56 that is formed to the elongate rigid shaft 52. The cable dressing clip 56 has a smaller diameter than the clip fastener 54 but is constructed similarly and operates similarly. The cable dressing clip 56 has a smaller diameter because the flexible cable 42 has a smaller diameter than the mid-section 36 (see FIG. 5A) of the strain relief member 34.

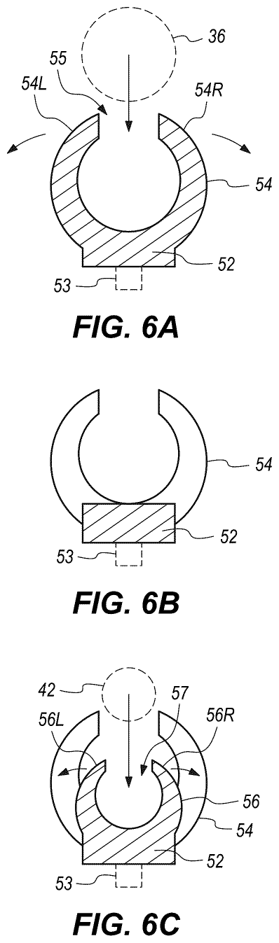

FIG. 6A is a cross-sectional view of the insertion and removal device 50 as in FIG. 5A but without the power cable 40 secured thereto. Accordingly, the clip fastener 54 and the elongate rigid shaft 52 are shown. In order to secure the strain relief member 36 between the two jaws 54L, 54R, the strain relief member 36 must be forcible pressed into the clip opening 55 until the two jaws 54L, 54R flex outward (see leftward and rightward arrows) and allow the strain relief member 36 to move into the interior area of the clip fastener 54. The clip fastener 54 preferably presses tightly against the strain relief member 36 to both secure the electrical plug and maintain the electrical plug in a distal orientation.

In FIGS. 6A-C, a dashed line illustrates an optional stiffening rib 53 that may be formed on one side of the elongate rigid shaft 52. The rib 53 preferably runs along the entire length of the elongate rigid shaft 52 but may be used along any portion thereof. In the illustrations of FIGS. 6A-C, the rectangular cross-section of the elongate rigid shaft 52 has a long dimension that runs from left to right and, therefore, will tend to prevent deflection of the shaft 52 to the left or right. However, the shaft 52 is illustrated with a narrower dimension that runs up and down and is therefore more likely to bend or deflect upward or downward. In that case, forming a rib 53 on the bottom side of the shaft 52 will provide additional resistance to such deflection.

FIG. 6B is a cross-sectional view of the insertion and removal device 50 as in FIG. 5B but without the power cable 40 secured thereto. Only the elongate rigid shaft 52 is shown in cross-section. However, the clip fastener 54 is shown in the background.

FIG. 6C is a cross-sectional view of the insertion and removal device 50 as in FIG. 5C but without the power cable 40 secured thereto. The cable dressing clip 56 and the elongate rigid shaft 52 are shown in cross-section. In order to secure the flexible cable 42 between the two jaws 56L, 56R, the flexible cable 42 must be forcible pressed into the clip opening 57 until the two jaws 56L, 56R flex outward (see leftward and rightward arrows) and allow the flexible cable 42 to move into the interior area of the cable dressing clip 56. It is not necessary for the cable dressing clip 56 to press against the sides of the flexible cable 42. Rather, the cable dressing clip 56 preferably prevents the flexible cable 42 from falling out so that the flexible cable 42 is unable to droop. In other words, the purpose of the cable dressing clip 56 is to hold the flexible cable 42 close to the elongate rigid shaft 52.

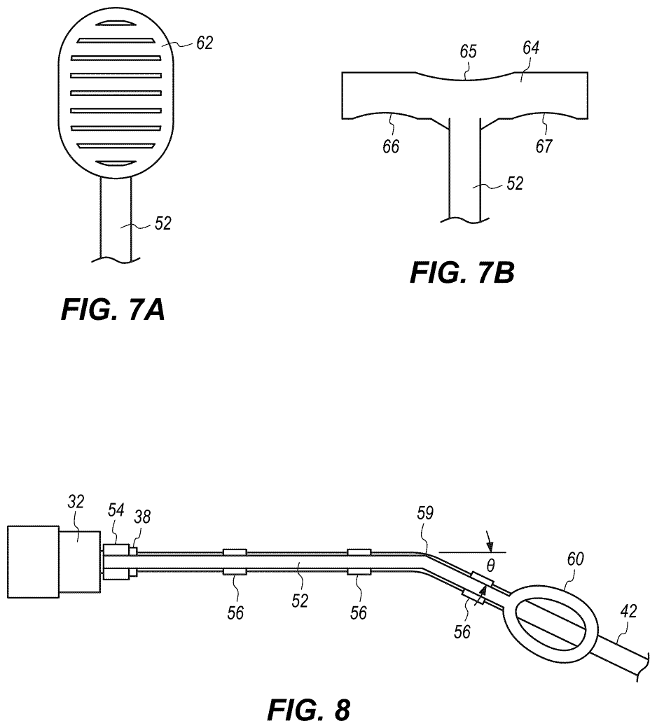

FIGS. 7A and 7B are diagrams of alternative configurations of a handle 60 at the proximate end of the elongate rigid shaft 52 according to additional embodiments. While FIGS. 2-4B illustrate the handle 60 as a finger loop, FIG. 7A illustrates a handle in the form of a paddle or plate 62 with a textured gripping surface. The paddle 62 may be pressed between two fingers, such as the pad of the thumb and the second knuckle of a bent index finger. FIG. 7B illustrates a handle in the form of a crossbar 64 (T-shaped handle). The top (distal face) may have a first recess for the pad of a thumb and the bottom (proximal face) may have a pair of recesses 66, 67 for the index and middle fingers. Other handle configurations can be imagined according to other embodiments.

FIG. 8 is a diagram of an alternative configuration of the elongate rigid shaft 52 including a bend according to one embodiment. The illustrated configuration is substantially the same as the elongate rigid shaft 52 shown in FIG. 4A, except that elongate rigid shaft 52 include a bend at point 59. The angle of the bend (Θ) may vary but preferably does not exceed about 30 degrees. However, the inclusion of a bend may enable the insertion and removal device 50 to extend around a corner or disposed the handle 60 in a position with more room for a human hand.

FIG. 9A is a perspective view of an IEC 14 male power cable connector or plug 30. The plug 30 includes three distally directed electrically conductive elements 31 for forming an electrical connection with a receptable of a PDU. The electrically conductive elements 31, such as flat blades and/or round pins, serve as the electrical contacts that fit into corresponding slots 21 in the electrical receptacle or socket 22 (see FIG. 3). However, the scope of the apparatus disclosed herein is not limited to any particular type of power cable or any particular type or standard of plug.

FIG. 9B is a perspective view of an IEC 13 female power cable connector or plug 70. The IEC 13 plug 70 may be provided at the opposing end of the flexible cable 42 from the IEC 14 plug shown in FIG. 9A. This is the type of plug that is typically used to connect to a server chassis. However, the scope of the apparatus disclosed herein is not limited to any particular type of power cable or any particular type or standard of plug.

Embodiments of the apparatus (insertion and removal device) 10 may be used with devices that deliver power and have female receptacles (like PDUs), such as a power distribution unit. In this case, the power cable would have a plug with male pins or elements that extend out. Alternatively, embodiments of the apparatus 10 may be used to with devices accepting power and having recessed male pins or elements. In that case, the power cable would have a plug with female pins (sockets). Of course, a power cable may have a first end with a male plug and a second end with a female plug. For example, a power cable may have an IEC 14 plug at one end and an IEC 13 plug at the other end.

The terminology used herein is for the purpose of describing particular embodiments only and is not intended to limit the scope of the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the embodiment.

The corresponding structures, materials, acts, and equivalents of all means or steps plus function elements in the claims below are intended to include any structure, material, or act for performing the function in combination with other claimed elements as specifically claimed. Embodiments have been presented for purposes of illustration and description, but it is not intended to be exhaustive or limited to the embodiments in the form disclosed. Many modifications and variations will be apparent to those of ordinary skill in the art after reading this disclosure. The disclosed embodiments were chosen and described as non-limiting examples to enable others of ordinary skill in the art to understand these embodiments and other embodiments involving modifications suited to a particular implementation.

What is claimed is:

1. An apparatus, comprising:
a rigid elongate shaft defining a longitudinal path between a proximal end and a distal end;
a clip fastener at the distal end of the rigid elongate shaft, wherein the clip fastener has a laterally directed clip opening dimensioned to receive a strain relief member of a rigid electrical plug body at a distal end of a power cable, and wherein the clip fastener is configured to receive and secure the strain relief member with the clip fastener positioned between the rigid electrical plug body and a ridge of the strain relief member; and
a handle at the proximal end of the rigid elongate shaft, wherein, with the clip fastener secured to the strain relief member, an application of pushing force to the handle in a distal direction toward a receptacle of a power distribution unit in line with the longitudinal path causes a set of electrically conductive elements secured to the rigid electrical plug body to connect electrically with the receptacle and an application of pulling force to the handle in a proximal direction away from the receptacle of the power distribution unit causes the set of electrically conductive elements to be disconnected from the receptacle.

2. The apparatus of claim 1, wherein the clip fastener is secured to the power cable before forming the electrical connection with the receptacle and remains secured to the power cable over a duration of the electrical connection so that the handle is ready to be used to disconnect the electrical connection.

3. The apparatus of claim 1, wherein the clip fastener has a distal edge and a proximal edge, and wherein, with the clip fastener secured to the strain relief member, the distal edge abuts the rigid electrical plug body and the proximal face abuts a ridge of the strain relief member.

4. The apparatus of claim 1, wherein the handle includes a finger loop that facilitates manual application of pushing force and/or pulling force to the rigid elongate shaft.

5. The apparatus of claim 1, wherein, with the clip fastener secured to the strain relief member, the elongate rigid shaft and the clip fastener have a cross-sectional profile that is inscribed within a cross-sectional profile of the rigid electrical plug body.

6. The apparatus of claim 1, wherein, with the clip fastener secured to the strain relief member of the rigid electrical plug body, the handle portion of the elongate rigid shaft can be manipulated to form the electrical connection between the set of electrically conductive elements to the receptacle of the power distribution unit, and wherein the receptacle is inaccessible to form the electrical connection by directly gripping the rigid electrical plug body with a human hand.

7. The apparatus of claim 1, wherein the longitudinal path of the rigid elongate shaft includes a bend so that the handle portion is disposed at an angle from a distal portion of the rigid elongate shaft that forms the clip fastener.

8. The apparatus of claim 1, wherein the set of electrically conductive elements are prongs extending from the rigid electrical plug body, and wherein the receptacle includes a set of slots for receiving the prongs.

9. The apparatus of claim 8, wherein, with the clip fastener secured to the strain relief member, the rigid electrical plug body is held in a position with the set of electrically conductive elements extending in the distal direction.

10. The apparatus of claim 1, further comprising:
one or more laterally directed cable dressing clips secured to the elongate shaft between the clip fastener and the handle, wherein each of the cable dressing clips is a press-fit clip that is secured to a flexible portion of the power cable by manually pressing the flexible portion into an opening in the cable dressing clip.

11. The apparatus of claim 10, wherein the one or more laterally directed cable dressing clips includes two to four cable dressing clips.

12. The apparatus of claim 1, wherein the clip fastener is a press-fit clip that is secured to the strain relief member of the power cable by manually pressing the strain relief member into the clip opening.

13. The apparatus of claim 12, wherein the clip fastener has an interior profile that includes a major arc of a circle.

14. The apparatus of claim 12, wherein the clip opening is smaller than an outer diameter of the strain relief member of the power cable, and wherein the clip fastener has first and second jaws that flex when the strain relief member is pressed therebetween.

15. The apparatus of claim 14, wherein the clip fastener opening is directed away from the rigid elongate shaft and the first and second jaws are symmetrical.

16. The apparatus of claim 1, wherein the elongate rigid shaft and the handle have a combined length that is sufficient to extend, with the clip fastener secured to the strain relief member and with the set of electrically conductive elements forming an electrical connection with the receptacle, from the strain relief member to a point rearward of a rear edge of a deep server that extends rearward of a rear flange of a server rack.

17. The apparatus of claim 16, wherein the power distribution unit is positioned in a side pocket of the server rack and secured to the rear flange in the server rack with the receptacles facing the rear of the server rack.

18. The apparatus of claim 17, wherein the deep server extends about 10 inches further rearward of the rear flange and the side pocket is less than 2 inches wide.

19. The apparatus of claim 1, further comprising:
a power cable including the flexible cable and a rigid electrical plug body at the distal end of the flexible cable, wherein the rigid electrical plug body includes a strain relief member around the flexible cable at a proximal end of the rigid electrical plug body and the set of electrically conductive elements for forming the electrical connection with the receptacle, wherein the strain relief member includes the ridge.

20. A method of using the apparatus of claim 1, comprising:
positioning the rigid elongate shaft along the power cable with the laterally directed clip opening facing the strain relief member of the rigid electrical plug body;
pushing the strain relief member into the clip opening until the clip fastener is secured to the strain relief member with the clip fastener positioned between the rigid electrical plug body and a ridge of the strain relief member;
pushing the handle in the distal direction toward the receptacle until the set of electrically conductive elements form an electrical connection with the receptacle; and
pulling the handle in a proximal direction away from the receptacle until the set of electrically conductive elements are disconnected from the receptacle.
